(19) United States
(12) Patent Application Publication
(10) Pub. No.: US 2001/0001983 A1
(43) Pub. Date: May 31, 2001

(54) LOCALIZED THERMO MANAGER FOR SEMICONDUCTOR DEVICES

(75) Inventor: CHANG H. KIM, WHIPPANY, NJ (US)

Correspondence Address: WILLIAM H. MURRAY, DUANE MORRIS & HECKSCHER LLP, ONE LIBERTY PLACE, PHILADELPHIA, PA, 19103-7396, US

(73) Assignee: DARIUS C. GAMBINO

(21) Appl. No.: 09/305,018

(22) Filed: May 4, 1999

(51) Int. Cl. F28F 7/00; F28D 15/00; F25D 23/12; G05D 23/00; H05K 7/20

(52) U.S. Cl. 165/299; 165/80.4; 165/104.33; 165/80.3; 62/259.2; 361/691; 361/700

(57) ABSTRACT

A method and apparatus for measuring and controlling the temperature of a semiconductor device is described. The temperature of a semiconductor device is controlled by measuring the temperature at the semiconductor device and adjusting the temperature by supplying a coolant to the semiconductor device over a coolant line. The amount of coolant which flows to the semiconductor device is controlled by a solenoid switch connected to a valve in the coolant line. A system for measuring and controlling the temperatures of multiple semiconductor devices is also described.

### FIELD OF THE INVENTION

The present invention relates to a method and apparatus for controlling the temperature of a semiconductor device.

### DESCRIPTION OF THE RELATED ART

Semiconductor devices are an important part of almost every computer on the market today. These devices control many of the inner workings of the computer. Failure of semiconductor devices often causes computer malfunctions. Semiconductor devices can fail for various reasons, and it is the task of the computer designer or repairer to decide what exactly has caused the failure. During a process known as “troubleshooting”, different parameters of the semiconductor devices of the computer are tested, in order to determine the source of the problem.

Troubleshooting is often difficult in complex systems which include numerous semiconductor devices. It may be necessary to remove individual devices from the system and test them individually to determine the source of the problem. This is often an arduous and time-consuming task.

Heat dissipation is a major concern in the design of most semiconductor devices. The flow of current through semiconductor devices creates heat which, in turn, raises the temperature of the devices. Devices which operate at temperatures which are too high (or too low) do not perform properly, and consequently, the performance of the system (of which the devices are a part) suffers. As stated above, when a system is experiencing problems, the individual devices are removed and tested to see if they are operating at temperatures which are too high. Hence, there is currently a need for testing and controlling the temperature of semiconductor devices while they are installed in a system.

### SUMMARY OF THE INVENTION

The present invention is a method and apparatus for measuring and controlling the temperature of a semiconductor device. The temperature of a semiconductor device is controlled by measuring the temperature at the semiconductor device and adjusting the temperature by supplying a coolant to the semiconductor device over a coolant line. A system for measuring and controlling the temperatures of multiple semiconductor devices is also described.

The above and other advantages and features of the present invention will be better understood from the following detailed description of the preferred embodiments of the invention which is provided in connection with the accompanying drawings.

### BRIEF DESCRIPTION OF THE DRAWINGS

FIG. 1 illustrates a first embodiment of the present invention.

FIG. 2 illustrates a second embodiment of the present invention.

### DETAILED DESCRIPTION

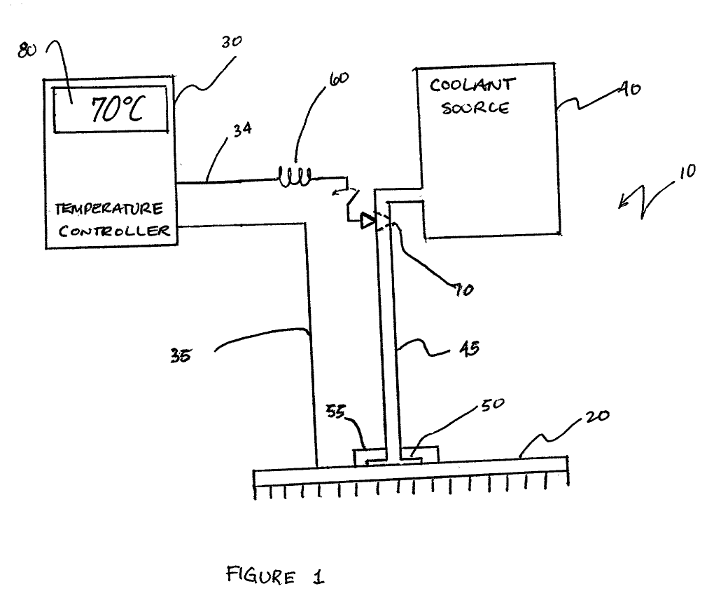

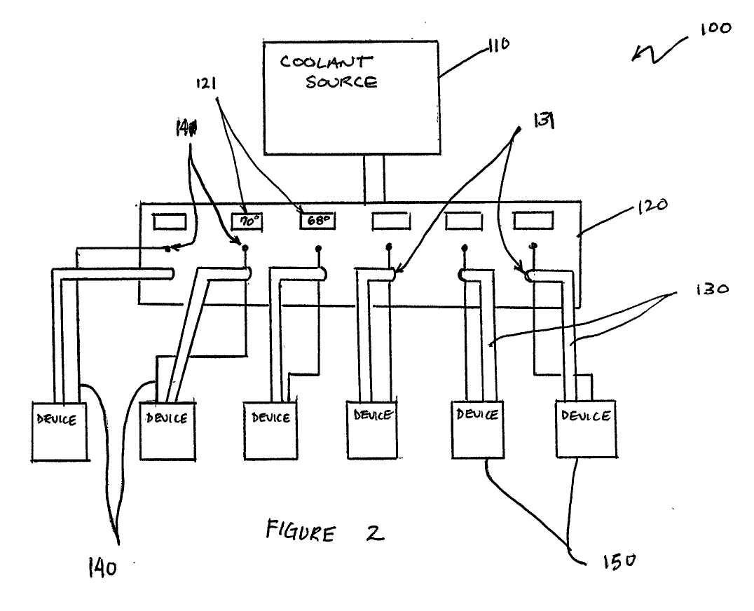

The present invention is a method and apparatus for controlling the temperature of a semiconductor device. FIG. 1 shows a first embodiment of the present invention where the temperature of a single semiconductor device is controlled. FIG. 2 shows a second embodiment of the present invention where the temperatures of a plurality of semiconductor devices are controlled.

FIG. 1 shows a first embodiment of the present invention. A control system 10 for controlling the temperature of a semiconductor device 20 is shown. The control system 10 includes a temperature controller 30 and a coolant source 40. The temperature controller 30 may be coupled to the coolant source 40 by a control line 34, and to the semiconductor device 20 by a thermocouple line 35. A solenoid switch 60 may be connected between the control line 34 and a coolant line 45 of the coolant source 40. The coolant line 45 runs between the coolant source 40 and the semiconductor device 20, and may include a flattened end 50 for securing the line to the top of the semiconductor device 20 by a thermally conductive adhesive 55. The solenoid switch 60 is attached to a valve 70 in the coolant line 45, and serves to open and close the valve 70 in response to the voltage present on the thermocouple line 35. Specifically, the thermocouple line 35 delivers a specific voltage to the temperature controller 30 based on the temperature of the semiconductor device 20 (or, more specifically, the difference between a thermocouple junction on the device and a reference thermocouple junction at a reference temperature). The temperature controller 30, in turn, sends a control signal on line 34 to cause the solenoid switch 60 to open or close based on the specific voltage sensed on thermocouple line 35. The temperature controller 30 may also include a display 80 for continually displaying the temperature of the semiconductor device 20.

An exemplary method of operating the control system 10 shown in FIG. 1 is next described. The temperature controller 30 continually monitors the temperature of the semiconductor device 20 and provides a readout of the temperature on the display 80. The solenoid switch 60 connected between control line 34 and the coolant line 45 is continually supplied with a control signal on line 34 representative of the temperature of the device 20 sensed on thermocouple line 35. When the voltage sensed on thermocouple line 35 exceeds a certain threshold temperature (set, for example, by the operator of the system), the control signal on control line 34 is altered by the temperature controller 30 so that the solenoid switch 60 opens, which in turn opens the valve 70 located in the coolant line 45. When the valve 70 opens, coolant fluid freely flows from the coolant source 40 to the semiconductor device 20. The application of the coolant to the semiconductor device serves to lower the temperature of the semiconductor device 20. The coolant may include such substances as liquid nitrogen, freon gas or other known coolant. Liquid carbon dioxide is used in the exemplary embodiment. As the temperature of the semiconductor device 20 is lowered, the thermocouple line 35 continues to monitor the temperature of the semiconductor device. When the voltage sensed on the thermocouple line 35 reaches a value corresponding to a temperature where the semiconductor device 20 no longer requires cooling, the control signal on line 34 is altered causing the solenoid switch 60 to close, thereby closing valve 70 in coolant line 45 and stopping the flow of coolant to the semiconductor device 20. The valve 70 remains closed until the temperature of the semiconductor device again reaches a level which causes the solenoid switch 60 to open again. The threshold temperature of the temperature controller 30 may be set by an operator by an external control panel (not shown) coupled to the controller.

FIG. 2 shows a second embodiment of the present invention where the temperature of a plurality of semiconductor devices is controlled. The system 100 includes a coolant source 110, a coolant control system 120, a plurality of coolant lines 130, and a plurality of thermocouple lines 140. The coolant lines 130 and the thermocouple lines 140 are connected between a plurality of semiconductor devices 150 and the coolant control system 120. The coolant control system 120 may include separate displays 121 for monitoring the temperature of each semiconductor device 150. Both the coolant lines 130 and thermocouple lines 140 are affixed to the coolant control system at respective ports 131, 141, so that they can be easily removed from the control system 120 if not in use. The coolant source 110 is also connected to the coolant control system 120 to supply coolant to the devices 150. As with the first embodiment, the coolant lines 130 may be connected to the devices 150 by a conductive adhesive or other similar means. The control line, solenoid switch and valve shown in FIG. 1, however, are contained inside the coolant control system 120 in this embodiment.

In operation, the coolant control system constantly monitors the temperature of each device 150 and releases coolant based on a threshold temperature set for each device. The temperature 121 of each semiconductor device 150 is continually displayed on respective displays 121. Inside the coolant control system 120, each device 150 has associated with it a solenoid switch and valve (not shown) for dispensing coolant to the device. The solenoid switch and valve operate similarly to the solenoid switch 60 and valve 70 in the first embodiment. When the temperature of a device 150 being monitored reaches the threshold temperature, the solenoid switch associated with the device 150 opens the respective valve in the coolant control system 120 to dispense coolant to the device over an associated coolant line 130. The threshold temperature for each device 150 can be set differently, and thus one device may have a threshold temperature of 70 degrees while another has a threshold temperature of 65 degrees. Accordingly, the second embodiment provides a method for controlling the temperature of a plurality of devices.

Although the above embodiments were described with reference to thermocouple lines which measured voltage, the invention is not limited thereto. The thermocouple lines may be used to measure current, power, electromotive force (EMF), or any other parameter known to those skilled in the art. Additionally, other temperature detection devices besides thermocouples may be used without departing from the scope of the invention, including thermistors, resistance temperature detectors (RTDs), and the like.

It should also be noted that even though the exemplary coolant lines 45 and 130 are directly connected to the semiconductor devices, the coolant lines may also terminate near the semiconductor devices (not shown). For example, the coolant lines may spray coolant (e.g. cooled gas) on the semiconductor device to achieve cooling.

Although the invention has been described in terms of exemplary embodiments, it is not limited thereto. Rather, the appended claim should be construed broadly, to include other variants and embodiments of the invention which may be made by those skilled in the art without departing from the scope and range of equivalents of the invention.

What is claimed is:

1. An apparatus for controlling the temperature of semiconductor device comprising:
a temperature controller that controls the temperature of the semiconductor device; and,
a coolant source for introducing a coolant to the semiconductor device under control of the controller, to regulate the temperature of the semiconductor device.

2. The apparatus of claim 1, wherein the temperature controller is connected to the semiconductor device by at least one thermocouple.

3. The apparatus of claim 1, wherein the coolant line is connected to the semiconductor device by a thermally conductive adhesive.

4. The apparatus of claim 1, further comprising a solenoid connected between the temperature controller and the coolant source, the temperature controller controlling the solenoid to regulate the flow of coolant from the coolant source.

5. The apparatus of claim 4, further comprising a valve in the coolant line, wherein the solenoid controls the valve so that coolant is supplied to the semiconductor device when the temperature controller indicates that the semiconductor device has reached a particular temperature.

6. The apparatus of claim 1, further comprising a sensor that provides signals representing the temperature of the semiconductor device to the controller.

7. The apparatus of claim 1, wherein the semiconductor device is a microchip.

8. An apparatus for controlling the temperature of at least one semiconductor device comprising:
a temperature controller, said controller connected to at least one semiconductor device; and,
at least one coolant line between the temperature controller and the at least one semiconductor device for introducing a coolant to the semiconductor device in order to regulate the temperature of the semiconductor device.

9. The apparatus of claim 8, wherein the temperature controller is connected to the at least one semiconductor device by at least one thermocouple.

10. The apparatus of claim 8, wherein the at least one coolant line is connected to the at least one semiconductor device by a thermally conductive adhesive.

11. The apparatus of claim 8, further comprising a solenoid connected between the temperature controller and the at least one coolant line, the temperature controller controlling the solenoid to regulate the flow of coolant from the coolant source.

12. The apparatus of claim 11, further comprising a valve in the coolant line, wherein the solenoid controls the valve so that coolant is supplied to the at least one semiconductor device when the temperature controller indicates that the at least one semiconductor device has reached a particular temperature.

13. The apparatus of claim 8, further comprising a sensor that provides signals representing the temperature of the semiconductor device to the controller.

14. The apparatus of claim 8, wherein the at least one semiconductor device is a microchip.

15. An apparatus for controlling the temperature of a plurality of semiconductor devices comprising:
a temperature controller that controls the temperature of a plurality of semiconductor devices; and,
a plurality of coolant lines between the temperature controller and the plurality of semiconductor devices for introducing a coolant to the semiconductor devices in order to control the temperature of the semiconductor devices.

16. A method for controlling the temperature of a semiconductor device comprising the steps of:
monitoring the temperature of a semiconductor device with a temperature controller; and,
introducing a coolant to the semiconductor device under control of the controller, to control the temperature of the semiconductor device.

17. The method of claim 16, wherein the monitoring step comprises monitoring over a thermocouple line.

18. The method of claim 16, further comprising the step of:
controlling a solenoid switch in response to the monitored temperature of the semiconductor device.

19. The method of claim 18, comprising the further step of:
providing signals representing the temperature of the semiconductor device to the solenoid switch to control the amount of coolant which is introduced to the semiconductor device.

20. The method of claim 16, comprising the further step of:
opening and closing a valve in the coolant line in response to the temperature monitored by the temperature controller.
